(19) United States
(12) Patent Application Publication
(10) Pub. No.: US 2025/0112036 A1
(43) Pub. Date: Apr. 3, 2025

(54) METHOD OF FORMING CARBON-CONTAINING FILM

(71) Applicant: Tokyo Electron Limited, Tokyo (JP)

(72) Inventors: Miyako KANEKO, Yamanashi (JP); Tadashi MITSUNARI, Yamanashi (JP); Naoko SUZUKI, Yamanashi (JP)

(21) Appl. No.: 18/980,360

(22) Filed: Dec. 13, 2024

Related U.S. Application Data
(63) Continuation of application No. PCT/JP2023/022995, filed on Jun. 21, 2023.

(30) Foreign Application Priority Data
Jun. 28, 2022 (JP) 2022-104014

(51) Int. Cl. H01L 21/02; C23C 16/26; H01J 37/32

(52) U.S. Cl. CPC H01L 21/02115; C23C 16/26; H01L 21/0228; H01J 37/32449; H01J 2237/3321

(57) ABSTRACT

A method of forming a carbon-containing film having a high etching resistance and a low stress is provided. The method of forming a carbon-containing film includes a first step of forming a first carbon-containing film on a substrate, and a second step of reforming a surface layer of the first carbon-containing film. The first carbon-containing film formed in the first step has a first film stress. The first carbon-containing film reformed in the second step has a second film stress. A difference between the first film stress and the second film stress is ±100 MPa or less.

### CROSS-REFERENCE TO RELATED APPLICATIONS

This application is a continuation application of International Application No. PCT/JP2023/022995, filed on Jun. 21, 2023, and designating the U.S., which is based upon and claims priority to Japanese Patent Application No. 2022-104014, filed on Jun. 28, 2022, the entire contents of which are incorporated herein by reference.

### BACKGROUND

### Technical Field

The present disclosure relates to a method of forming a carbon-containing film.

### Background Art

Japanese Patent Application Laid-Open Publication No. 2007-224383 discloses a method of forming an amorphous carbon film, including the steps of: setting a substrate in a processing container; supplying a processing gas containing carbon, hydrogen and oxygen into the processing container; and heating the substrate in the processing container to decompose the processing gas and deposit an amorphous carbon film on the substrate.

### SUMMARY

In one aspect, the present disclosure provides a method of forming a carbon-containing film having a high etching resistance and a low stress.

To solve the problem described above, one embodiment can provide a method of forming a carbon-containing film, including: forming a first carbon-containing film on a substrate; and reforming a surface layer of the first carbon-containing film, wherein the first carbon-containing film formed in the forming has a first film stress, the first carbon-containing film reformed in the reforming has a second film stress, and a difference between the first film stress and the second film stress is ±100 MPa or less.

According to one aspect, a method of forming a carbon-containing film having a high etching resistance and a low stress can be provided.

### BRIEF DESCRIPTION OF THE DRAWINGS

FIG. 1 is an example of a configuration diagram of a resist coating apparatus;

FIG. 2 is an example of a configuration diagram of an electron beam irradiation apparatus;

FIG. 3 is an example of a configuration diagram of an ion implantation apparatus;

FIG. 4 is an example of a configuration diagram of a plasma processing apparatus;

FIG. 5 is an example of a flow chart illustrating a method of forming a carbon-containing film;

FIG. 6A is an example of a cross-sectional schematic view illustrating a state of a carbon-containing film formed on a substrate;

FIG. 6B is an example of a cross-sectional schematic view illustrating a state of a carbon-containing film formed on a substrate;

FIG. 7 is an example of a graph indicating the relationship between electron beam irradiation and the film thickness of KrF resist films;

FIG. 8 is an example of a graph indicating the relationship between electron beam irradiation and the film thickness of SOC films;

FIG. 9A is a graph indicating an example of the result of Raman spectroscopy of a KrF resist film;

FIG. 9B is a graph indicating an example of the result of Raman spectroscopy of a KrF resist film;

FIG. 9C is a graph indicating an example of the result of Raman spectroscopy of a KrF resist film;

FIG. 9D is a graph indicating an example of the result of Raman spectroscopy of a KrF resist film;

FIG. 10 is an example of a graph indicating the relationship between ion implantation and the thickness of KrF resist films;

FIG. 11A is a graph indicating an example of the result of Raman spectroscopy of a SOC film;

FIG. 11B is a graph indicating an example of the result of Raman spectroscopy of a SOC film;

FIG. 11C is a graph indicating an example of the result of Raman spectroscopy of a SOC film;

FIG. 11D is a graph indicating an example of the result of Raman spectroscopy of a SOC film;

FIG. 12 is an example of a graph indicating the relationship between ion implantation and the thickness of SOC films;

FIG. 13 is an example of a graph indicating the relationship between etching rate and film stress of KrF resist films;

FIG. 14 is an example of a graph indicating the relationship between etching rate and film stress of SOC films;

FIG. 15 is an example of a graph indicating the relationship between film stress and etching rate of a carbon-containing film;

FIG. 16A is an example of a cross-sectional schematic view illustrating another configuration state of a carbon-containing film formed on a substrate;

FIG. 16B is an example of a cross-sectional schematic view illustrating another configuration state of a carbon-containing film formed on a substrate;

FIG. 17A is a cross-sectional schematic view of a substrate W illustrating substrate warpage when a carbon-containing film is formed;

FIG. 17B is a cross-sectional schematic view of a substrate W illustrating substrate warpage when a carbon-containing film is formed;

FIG. 18A is an example of a cross-sectional schematic view of a substrate W illustrating a process for forming a carbon-containing film by inhibiting substrate warpage;

FIG. 18B is an example of a cross-sectional schematic view of a substrate W illustrating a process for forming a carbon-containing film by inhibiting substrate warpage; and

FIG. 18C is an example of a cross-sectional schematic view of a substrate W illustrating a process for forming a carbon-containing film by inhibiting substrate warpage.

### DETAILED DESCRIPTION OF THE INVENTION

Various illustrative embodiments will now be described in detail with reference to the drawings. In each of the drawings, the same or equivalent parts are denoted by the same reference numerals.

### <Resist Coating Apparatus 100>

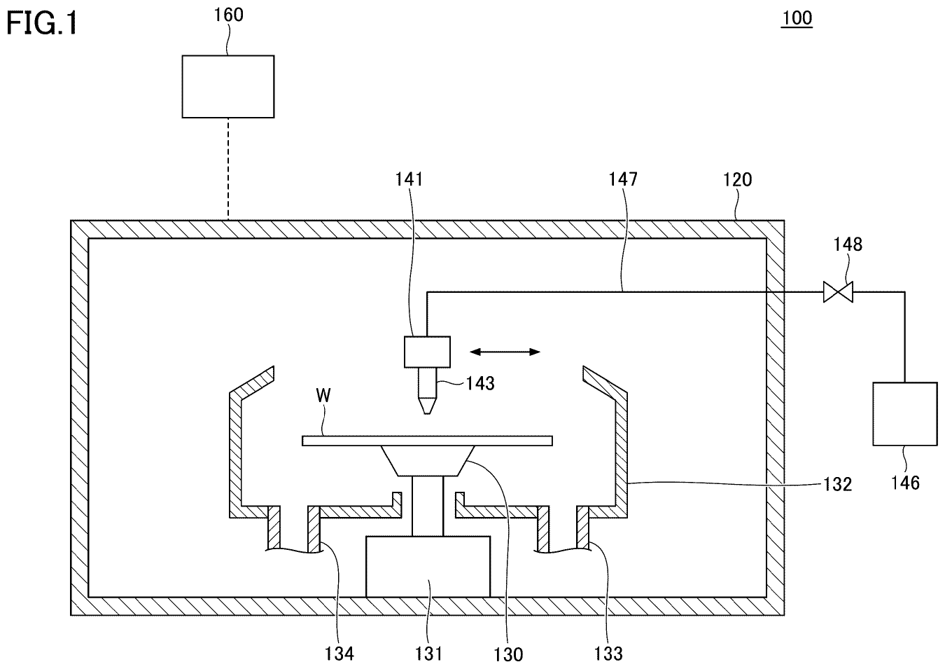

First, a resist coating apparatus 100 as a film forming apparatus for forming a carbon-containing film on a substrate W such as a semiconductor wafer or the like will be described with reference to FIG. 1. FIG. 1 is an example of a configuration diagram of the resist coating apparatus 100. A carbon-containing film to be formed on the substrate W is used as, for example, a hard mask when the substrate W is etched.

The resist coating apparatus 100 includes a casing 120. A spin chuck 130 for holding the substrate W is provided in the central part of the casing 120. The spin chuck 130 has a horizontal upper surface, and, for example, a suction port (not illustrated) for sucking the substrate W is provided on the upper surface. By suctioning from the suction port, the spin chuck 130 can attract the substrate W to the upper surface of the spin chuck 130 and hold it thereon. The spin chuck 130 is not limited to attraction-holding by suction, and may, for example, hold the substrate W by mechanically pressing an edge of the substrate W.

The spin chuck 130 has a chuck driving mechanism 131 including, for example, a motor and the like. The chuck driving mechanism 131 is configured to rotate the spin chuck 130 at a predetermined speed. The chuck driving mechanism 131 includes an elevation driving source such as a cylinder or the like. The elevation driving source of the chuck driving mechanism 131 is configured to move the spin chuck 130 up and down.

Around the spin chuck 130, there is provided a cup 132 for receiving and recovering a liquid scattered or falling from the substrate W. A discharge pipe 133 for discharging the recovered liquid and a gas exhaust pipe 134 for exhausting the atmosphere in the cup 132 are connected to the lower surface of the cup 132.

An arm 141 is configured to be movable in the horizontal direction along a rail (not illustrated). A resist liquid nozzle 143 for discharging a resist liquid serving as a coating liquid is supported on the arm 141.

A supply pipe 147 communicating with a resist liquid supply source 146 is connected to the resist liquid nozzle 143. The resist liquid supply source 146 in this embodiment stores the resist liquid. The supply pipe 147 is provided with a valve 148, and it is possible to switch ON or OFF the discharging of the resist liquid by opening or closing the valve 148.

Rotation of the spin chuck 130 by the chuck driving mechanism 131 is controlled by a control part 160. Transfer of the resist liquid nozzle 143 by the arm 141 and switching ON or OFF of resist liquid discharging from the resist liquid nozzle 143 by the valve 148 are also controlled by the control part 160. The control part 160 is composed of a computer including, for example, a CPU, a memory, and the like, and can realize a resist coating process, a drying process, and the like of the resist coating apparatus 100 by, for example, executing a program stored in the memory.

In the resist coating process, the control part 160 controls the chuck driving mechanism 131 to rotate the spin chuck 130, to which the substrate W is attracted, at high speed, and controls the arm 141 and the valve 148 to supply the resist liquid from the resist liquid nozzle 143 to the center of the surface of the substrate W, to thereby diffuse the resist liquid to the outer peripheral side of the substrate W under the effect of a centrifugal force and apply the resist liquid to the surface of the substrate W.

Here, as the resist liquid, a resist liquid containing carbon (C) can be used. As the resist liquid containing carbon (C), a resist liquid for forming a KrF resist film, a resist liquid for forming a Spin-on Carbon (SOC) film, and the like can be used. As the resist liquid for forming a KrF resist film, for example, a mixed liquid of ethyl lactate and an aromatic acrylic resin can be used. As the resist liquid for forming a SOC film, for example, a mixed liquid of propylene glycol monomethyl ether acetate (PGMEA), propylene glycol monoethyl ether (PGEE), a resin component, an additive, and the like can be used. Moreover, as the resist liquid for forming a SOC film, for example, a mixed liquid of propylene glycol monomethyl ether acetate (PGMEA), cyclohexanone, a resin component, an additive, and the like can be used.

In the drying process, the control part 160 controls the arm 141 and the valve 148 to stop the supply of the resist liquid, and controls the chuck driving mechanism 131 to rotate the spin chuck 130, to which the substrate W is attracted, at a high speed, to thereby dry the resist liquid applied to the substrate W.

In this way, a coating film of the resist liquid is formed on the surface of the substrate W through the resist coating process and the drying process. By using the resist liquid containing carbon (C), the resist coating apparatus 100 forms a carbon-containing film (also referred to as an organic film) on the surface of the substrate W.

The substrate W on which the coating film is formed is conveyed from the resist coating apparatus 100 to a baking apparatus (not illustrated). The baking apparatus includes a mounting part on which the substrate W is mounted, and a heater for heating the substrate W mounted on the mounting part. By baking (heating) the substrate W, the baking apparatus solidifies or polymerizes the carbon-containing film (the coating film of the resist liquid) formed on the surface of the substrate W, to remove any excess solvent.

### <Electron Beam Irradiation Apparatus 200>

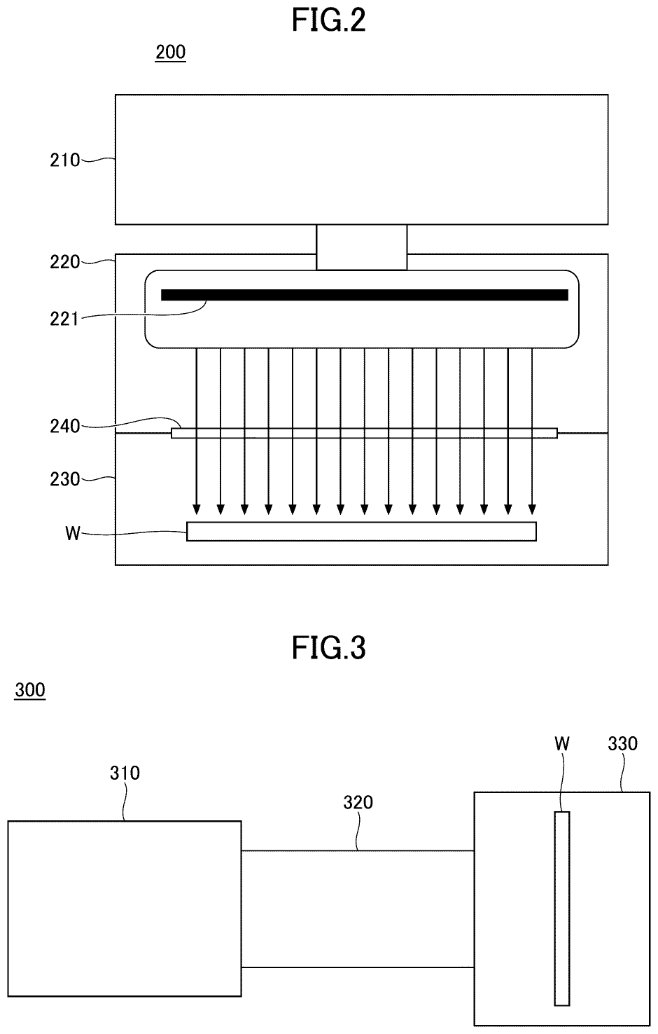

Next, an electron beam irradiation apparatus 200 for irradiating the substrate W on which the carbon-containing film is formed with an electron beam will be described with reference to FIG. 2. FIG. 2 is an example of a configuration diagram of the electron beam irradiation apparatus 200.

The electron beam irradiation apparatus 200 includes a power source 210, a vacuum chamber 220 including a filament 221, and an open-air chamber 230 in which a substrate W is set. A window foil 240 through which an electron beam can pass is provided between the vacuum chamber 220 and the open-air chamber 230. The power source 210 applies a voltage to the filament 221. As a result, electrons are emitted from the filament 221. The power source 210 also generates a high voltage for accelerating electrons. The accelerated electron beams are schematically illustrated by arrows. Thus, the electron beam irradiation apparatus 200 irradiates the substrate W with high-speed electron beams.

### <Ion Implantation Apparatus 300>

Next, an ion implantation apparatus 300 for implanting ions into the substrate W on which the carbon-containing film is formed will be described with reference to FIG. 3. FIG. 3 is an example of a configuration diagram of the ion implantation apparatus 300.

The ion implantation apparatus 300 includes a high-voltage part 310, a transporting part 320, and a process chamber 330. The high-voltage part 310 includes an ion generation source, an ion withdrawing part, a mass spectrometry part, and a slit. The ion generation source generates ions to be implanted into the substrate W. The ion withdrawing part extracts generated ions from the ion generation source. The mass spectrometry part deflects the travelling direction of ions by a magnetic field. Then, ions pass through the slit, such that desired ions are extracted. The transporting part 320 includes an acceleration part and a scanning part. The acceleration part accelerates the ions that have passed through the slit. The scanning part scans the accelerated ion beams. A substrate W is set in the process chamber 330. The substrate W is irradiated with the ion beams scanned by the ion beam scanning part. In this way, the ion implantation apparatus 300 implants ions into the substrate W.

### <Plasma Processing Apparatus 400>

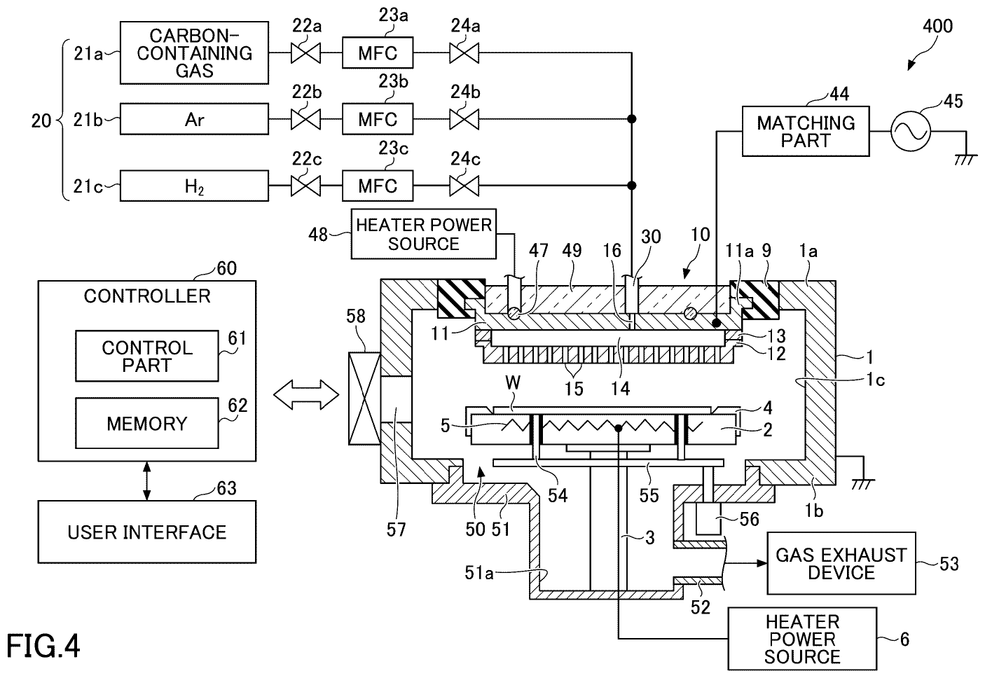

Next, a plasma processing apparatus 400 for forming a carbon-containing film on a substrate W such as a semiconductor wafer or the like and irradiating the substrate W on which the carbon-containing film is formed with a plasma will be described with reference to FIG. 4. FIG. 4 is an example of a configuration diagram of the plasma processing apparatus 400. The carbon-containing film formed on the substrate W is used as, for example, a hard mask when the substrate W is subjected to etching.

The plasma processing apparatus 400 includes a chamber 1 formed in a substantially cylindrical shape, of which an inner wall surface contains anodized aluminum or the like. The chamber 1 is grounded. A susceptor 2 is provided inside the chamber 1. The susceptor 2 is supported by a substantially cylindrical support member 3 provided in a lower central portion of the chamber 1. The susceptor 2 is a mounting table (stage) for horizontally supporting a substrate W and is made of, for example, a ceramic material such as aluminum nitride (AlN) or the like, or a metal material such as aluminum, nickel alloy, or the like. The susceptor 2 is grounded via a support member 3.

A guide ring 4 for guiding the substrate W is provided on the outer edge of the susceptor 2. A heater 5 made of a high-melting-point metal such as molybdenum or the like is embedded in the susceptor 2. A heater power source 6 is connected to the heater 5. The heater 5 heats the substrate W supported by the susceptor 2 to a predetermined temperature by electric power supplied from the heater power source 6.

A shower head 10 is provided on a ceiling wall 1a of the chamber 1 via an insulating member 9. The shower head 10 in this embodiment is a pre-mix type shower head, and includes a base member 11 and a shower plate 12. The outer peripheral portion of the shower plate 12 is fixed to the base member 11 via an intermediate member 13 having a substantially annular shape for preventing sticking.

The shower plate 12 has a flange shape, and a recess is formed in the shower plate 12. That is, a gas diffusion space 14 is formed between the base member 11 and the shower plate 12. A flange part 11a is formed on the outer peripheral portion of the base member 11, and the base member 11 is supported by the insulating member 9 via the flange part 11a.

A plurality of gas discharge holes 15 are formed in the shower plate 12. A gas inlet hole 16 is formed in approximately the center of the base member 11. The gas inlet hole 16 is connected to a gas supply mechanism 20 through a pipe 30.

The gas supply mechanism 20 includes a supply source 21a of a carbon-containing gas (for example, CₓH_{y}: x is an integer greater than or equal to 1 and y is an integer greater than or equal to 0), a supply source 21b of a noble gas, and a supply source 21c of a hydrogen-containing gas (for example, H₂). In this embodiment, the noble gas is, for example, Ar gas.

The supply source 21a is connected to the pipe 30 via a valve 22a, a mass flow controller (MFC) 23a, and a valve 24a. The supply source 21b is connected to the pipe 30 via a valve 22b, an MFC 23b, and a valve 24b. The supply source 21c is connected to the pipe 30 via a valve 22c, an MFC 23c, and a valve 24c. The processing gas supplied into the gas diffusion space 14 through the pipe 30 diffuses in the gas diffusion space 14, and is discharged into the chamber 1 through the gas discharge holes 15 in the form of a shower.

The base member 11 is connected to an RF (Radio Frequency) power source 45 via a matching part 44. The RF power source 45 supplies RF power for plasma formation to the base member 11 via the matching part 44. The RF power supplied to the base member 11 is radiated into the chamber 1 via the intermediate member 13 and the shower plate 12. The processing gas (e.g., the hydrogen-containing gas) supplied into the chamber 1 is formed into a plasma by the RF power radiated into the chamber 1. In this way, a plasma of the hydrogen-containing gas is formed, and the substrate W is irradiated with the plasma of the processing gas. In this embodiment, the shower head 10 also functions as an upper electrode of parallel plate electrodes. On the other hand, the susceptor 2 also functions as a lower electrode of the parallel plate electrodes. The supply of the RF power is not limited to supply to only the upper electrode. For example, the RF power may be supplied to both the upper electrode and the lower electrode, or two different frequencies may be supplied to the upper electrode and the lower electrode, respectively.

The base member 11 of the shower head 10 is provided with a heater 47. The heater 47 is connected to a heater power source 48. The heater 47 heats the shower head 10 to a predetermined temperature by electric power supplied from the heater power source 48. Thus, the shower plate 12 is heated to, for example, 350° C. or higher. A heat insulating member 49 is provided on the upper surface of the base member 11. The member for heating the shower plate 12 is not limited to the heater. For example, the shower head 10 may be provided with a refrigerant passage such that the shower plate 12 is heated by a refrigerant device such as a chiller.

A substantially circular opening 50 is formed in an approximately central portion of a bottom wall 1b of the chamber 1. The opening 50 in the bottom wall 1b is provided with a gas exhaust chamber 51 projecting downward so as to cover the opening 50. The gas exhaust chamber 51 is made of aluminum or the like that is anodized on the surface of an inner wall 51a. The gas exhaust chamber 51 is grounded via the chamber 1. A gas exhaust pipe 52 is connected to the side wall of the gas exhaust chamber 51. A gas exhaust device 53 including a vacuum pump is connected to the gas exhaust pipe 52. The gas exhaust device 53 can reduce the pressure in the chamber 1 to a predetermined degree of vacuum.

When the processing gas is formed into a plasma in the chamber 1, a part of the active species contained in the plasma also flows into the gas exhaust chamber 51. As a result, a film containing the metal element is deposited also on the inner wall 51a of the gas exhaust chamber 51.

The susceptor 2 includes a plurality of (for example, three) lift pins 54 that can project from and retract into the surface of the susceptor 2 for moving up or down the substrate W. The plurality of lift pins 54 are supported by a support plate 55. The support plate 55 moves up or down by being driven by a driving mechanism 56. As the support plate 55 is moved up or down, the plurality of lift pins 54 are moved up or down.

In the side wall of the chamber 1, a conveying port 57 is provided for conveying a substrate W to and from a substrate conveying chamber (not illustrated) provided adjacent to the chamber 1. The conveying port 57 is opened and closed by a gate valve 58.

The plasma processing apparatus 400 includes a controller 60. The controller 60 is, for example, a computer, and includes a control part 61 and a memory 62. The memory 62 previously stores programs and the like for controlling various processes performed in the plasma processing apparatus 400. The control part 61 controls each part of the plasma processing apparatus 400 by reading and executing a program stored in the memory 62. The controller 60 is connected to a user interface 63. By executing a program stored in the memory 62, for example, the controller 60 can realize a carbon-containing film formation process, a plasma irradiation process, and the like in the plasma processing apparatus 400.

In the carbon-containing film formation process, the controller 60 controls the gas exhaust device 53 to depressurize the chamber 1 to a predetermined vacuum atmosphere, controls the heater power source 6 to heat the substrate W supported by the susceptor 2 to a predetermined temperature, and controls the gas supply mechanism 20 to supply the carbon-containing gas as a film formation gas for a carbon-containing film, the hydrogen-containing gas as a reaction gas, and the noble gas as a dilution gas into the chamber 1. In this way, the plasma processing apparatus 400 forms a carbon-containing film (also referred to as an organic film) on the surface of the substrate W by CVD (Chemical Vapor Deposition) processing.

In the plasma irradiation step, the controller 60 controls the gas exhaust device 53 to depressurize the chamber 1 to a predetermined vacuum atmosphere, controls the RF power source 45 to supply RF power for plasma formation to the base member 11, and controls the gas supply mechanism 20 to supply the hydrogen-containing gas and the noble gas into the chamber 1, thereby forming a hydrogen plasma in the chamber 1. In this way, the plasma processing apparatus 400 irradiates the substrate W on which the carbon-containing film is formed with a plasma.

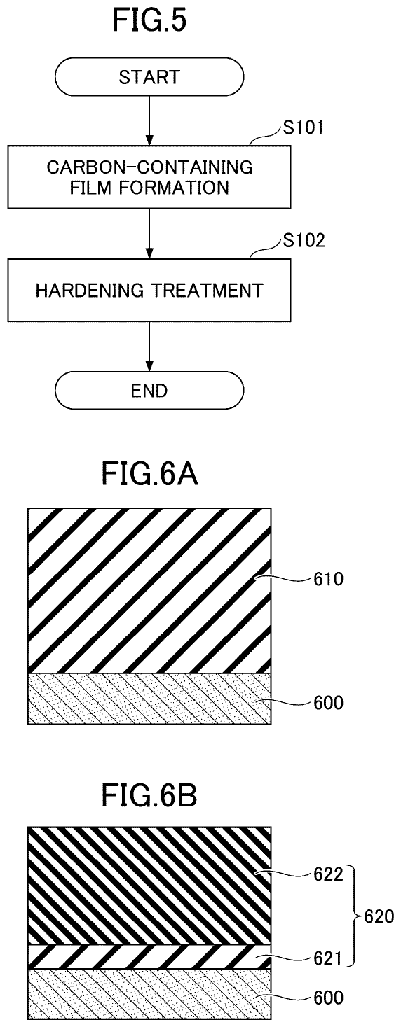

Next, the method of forming a carbon-containing film on a substrate W will be described with reference to FIGS. 5 to 6B. FIG. 5 is an example of a flowchart illustrating the carbon-containing film forming method of forming a carbon-containing film on the substrate W. FIGS. 6A and 6B are examples of schematic cross-sectional views illustrating the states of the carbon-containing film formed on the substrate W.

In step S101, a carbon-containing film (first carbon-containing film) 610 is formed on the substrate W. FIG. 6A is an example of a schematic cross-sectional view illustrating the state of the carbon-containing film 610 formed on the substrate W in step S101.

Here, the carbon-containing film 610 is formed on a silicon layer 600 of the substrate W using, for example, the resist coating apparatus 100 (see FIG. 1) and a baking apparatus (not illustrated). As the carbon-containing film 610, for example, any one of a KrF resist film, an SOC film, or the like is formed.

In step S102, a hardening treatment (reforming treatment) for reforming the surface layer of the carbon-containing film 610 on the substrate W is performed. FIG. 6B is an example of a schematic cross-sectional view illustrating the state of a carbon-containing film 620 formed on the substrate W in step S102.

As the hardening treatment, the carbon-containing film 610 formed on the substrate W is irradiated with electron beams using, for example, the electron beam irradiation apparatus 200 (see FIG. 2). Alternatively, ion implantation is performed on the carbon-containing film 610 formed on the substrate W using the ion implantation apparatus 300 (see FIG. 3).

When the carbon-containing film 610 (see FIG. 6A) is subjected to the hardening treatment (electron beam irradiation or ion implantation), two layers, namely a carbon-containing film (first region) 621 on the substrate W side (lower layer); and a reformed carbon-containing film (second region) 622 on the surface layer side (upper layer) of the carbon-containing film 620 are formed as the carbon-containing film 620. The lower carbon-containing film 621 is a region remaining unhardened (unirradiated with electron beams or un-implanted with ions), and has a low film stress (low stress) characteristic like the carbon-containing film 610. The upper carbon-containing film 622 is a region that is hardened (irradiated with electron beams or implanted with ions), and has a film density and a film stress (high stress) that are greater than those of the carbon-containing film 610, to have a high dry etching resistance.

The carbon-containing film has been described as being formed on the substrate W by application (spin coating) using the resist coating apparatus 100, but this is non-limiting. The carbon-containing film may be formed on the substrate W by CVD using the plasma processing apparatus 400 (see FIG. 4).

The hardening treatment of the carbon-containing film 610 is not limited to electron beam irradiation or ion implantation, but may be plasma irradiation. The carbon-containing film 610 on the substrate W may be hardened by irradiation of the substrate W with a hydrogen plasma using the plasma processing apparatus 400 (see FIG. 4).

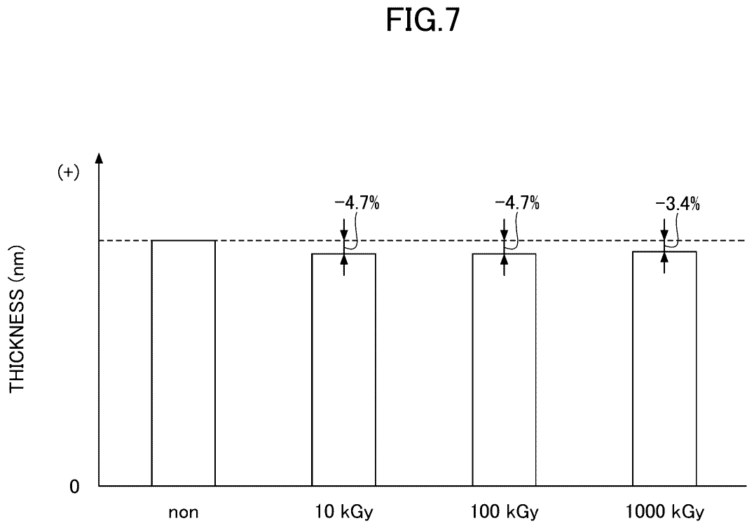

Here, the carbon-containing film 620 obtained by applying hardening treatment, which is either electron beam irradiation or ion implantation, to the carbon-containing film 610 formed on the substrate W by application (spin-coating) will be described with reference to FIGS. 7 to 12. In the following description, KrF resist films and SOC films will be described as the carbon-containing film.

First, the measurement result of electron beam irradiation on KrF resist films will be described with reference to FIG. 7. FIG. 7 is an example of a graph indicating the relationship between electron beam irradiation and the film thickness of KrF resist films. In FIG. 7, the film thickness (THICKNESS (nm)) of an untreated (non) KrF resist film, a KrF resist film irradiated with electron beams at an absorption dose of 10 kGy, a KrF resist film irradiated with electron beams at an absorption dose of 100 kGy, and a KrF resist film irradiated with electron beams at an absorption dose of 1,000 kGy is indicated by bar graph length. The ratio (%) at which each KrF resist film irradiated with electron beams was reduced with respect to the untreated (non) KrF resist film is also indicated.

As illustrated in FIG. 7, it was confirmed that the film thickness of the KrF resist films (carbon-containing films) irradiated with electron beams was reduced. In other words, the reduction in the film thickness indicates an equivalent increase in the film density. In a SEM image (not illustrated) of a cross-section of the substrate W on which each KrF resist film was formed, no two-layer structure including an upper layer and a lower layer was observed in the carbon-containing film. In the result of Raman spectroscopy, there was no significant change between the detected waveforms of the untreated (non) KrF resist film and the KrF resist films irradiated with electron beams.

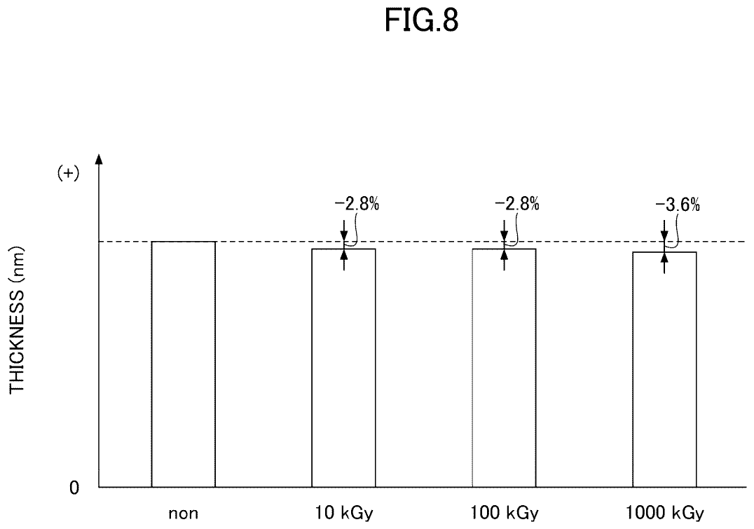

Next, the measurement result of electron beam irradiation on SOC films will be described with reference to FIG. 8. FIG. 8 is an example of a graph indicating the relationship between electron beam irradiation and the film thickness of the SOC films. In FIG. 8, the film thickness (THICKNESS (nm)) of an untreated (non) SOC film, a SOC film irradiated with electron beams at an absorption dose of 10 kGy, a SOC film irradiated with electron beams at an absorption dose of 100 kGy, and a SOC film irradiated with electron beams at an absorption dose of 1,000 kGy is indicated by bar graph length. The ratio (%) at which each SOC film irradiated with electron beams was reduced with respect to the untreated (non) SOC film is also indicated.

As illustrated in FIG. 8, it was confirmed that the film thickness of the SOC films (carbon-containing films) irradiated with electron beams was reduced. In other words, the reduction in the film thickness indicates an equivalent increase in the film density. In a SEM image (not illustrated) of a cross-section of the substrate W on which each SOC film was formed, no two-layer structure including an upper layer and a lower layer was observed in the carbon-containing film. In the result of Raman spectroscopy, there was no significant change between the detected waveforms of the untreated (non) SOC film and the SOC films irradiated with electron beams.

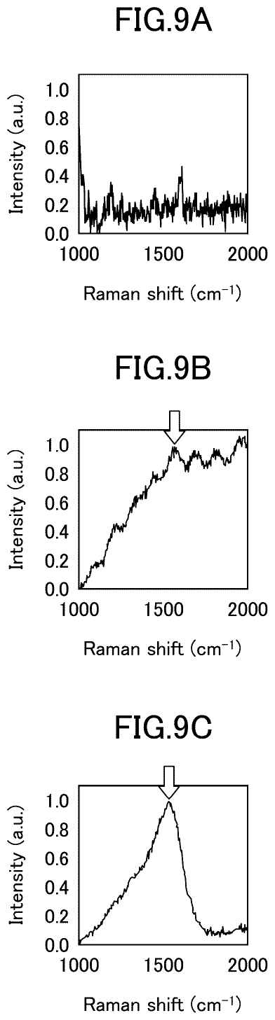

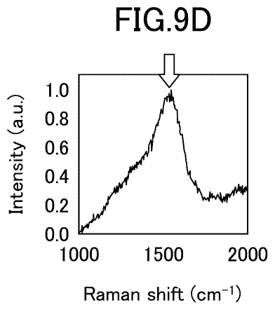

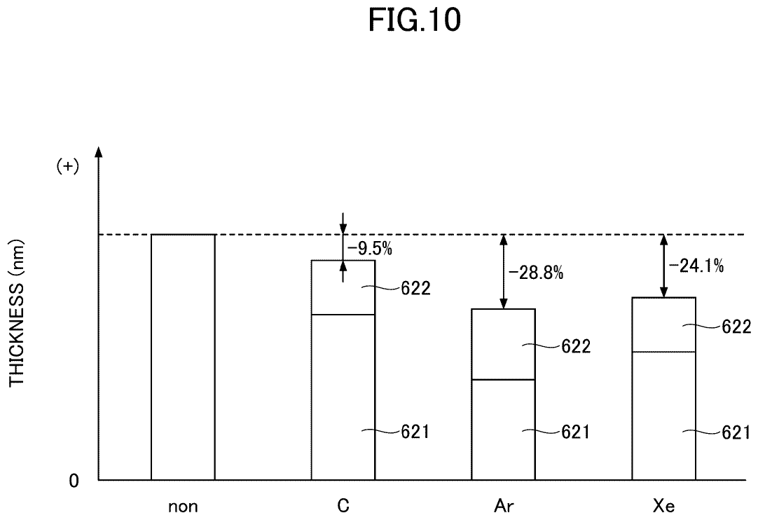

Next, the measurement results of ion implantation into KrF resist films will be described with reference to FIGS. 9A to 10. FIGS. 9A to 9D are graphs indicating examples of the results of Raman spectroscopy of KrF resist films. FIG. 9A indicates the result of an untreated (non) carbon-containing film 610, FIG. 9B indicates the result of C (carbon) ion implantation, FIG. 9C indicates the result of Ar (argon) ion implantation, and FIG. 9D indicates the result of Xe (xenon) ion implantation.

When ions are implanted into the substrate W using the ion implantation apparatus 300, ions are implanted into a shallow position of the carbon-containing film (a position close to the surface of the carbon-containing film) when the implantation energy of ions is small, and ions are implanted into a deep position of the carbon-containing film (a position away from the surface of the carbon-containing film) when the implantation energy of ions is large. Therefore, control of the implantation amount at an implantation energy causes ions to be implanted substantially uniformly from the surface of the carbon-containing film to a predetermined depth, and inhibits ions from being implanted below the predetermined depth. Thus, as illustrated in FIG. 6B, the carbon-containing film 621 into which no ions are implanted and the carbon-containing film 622 into which ions are implanted can be formed.

In the case of C (carbon) ion implantation, the implantation energy may be, for example, from 1 to 20 [keV], and the implantation amount may be, for example, in a range of 1×10¹⁴ to 5×10¹⁴ [atoms/cm²]. In the case of Ar (argon) ion implantation, the implantation energy may be, for example, 1 to 100 [keV], and the implantation amount may be, for example, in a range of 5×10¹⁴ to 5×10¹⁶ [atoms/cm²]. In the case of Xe (xenon) ion implantation, the implantation energy may be, for example, 1 to 200 [keV], and the implantation amount may be, for example, in a range of 1×10¹⁴ to 5×10¹⁵ [atoms/cm²].

As FIGS. 9A to 9D are illustrated by comparison, a peak was confirmed at a position indicated by outline arrow in FIGS. 9B to 9D. This peak indicates that DLC (diamond-like carbon) was formed. In other words, this indicates that implantation of C ions, Ar ions, or Xe ions into the KrF resist film promoted change of the carbon-containing film from PLC (polymer-like carbon) to DLC (diamond-like carbon).

FIG. 10 is an example of a graph indicating the relationship between ion implantation and the film thickness of KrF resist films. In FIG. 10, the film thickness (THICKNESS (nm)) of an untreated (non) KrF resist film, a KrF resist film implanted with C (carbon) ions, a KrF resist film implanted with Ar (argon) ions, and a KrF resist film implanted with Xe (xenon) ions is indicated by bar graph length. The ratio (%) at which each KrF resist film implanted with ions was reduced with respect to the untreated (non) KrF resist film is also indicated.

As illustrated in FIG. 10, it was confirmed that the film thickness of the KrF resist films (carbon-containing films) implanted with ions was reduced. In other words, the reduction in the film thickness indicates an equivalent increase in the film density. From a SEM image (not illustrated) of a cross-section of the substrate W on which each KrF resist film was formed, it was confirmed that the KrF resist film implanted with ions changed into a two-layer structure including a lower carbon-containing film 621 and an upper carbon-containing film 622.

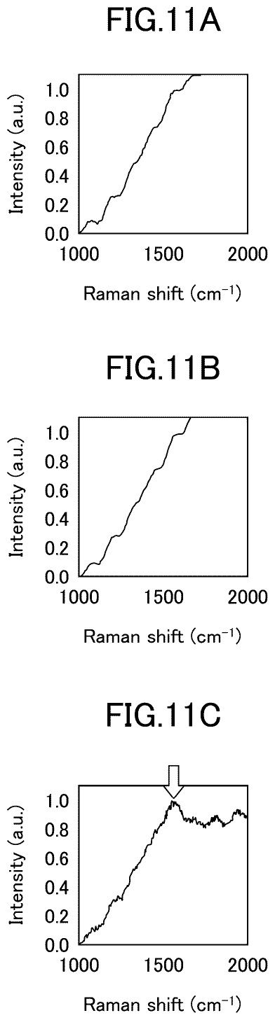

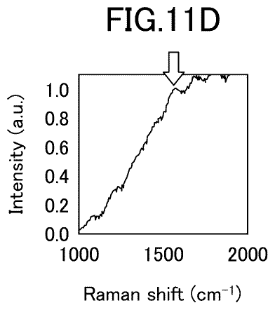

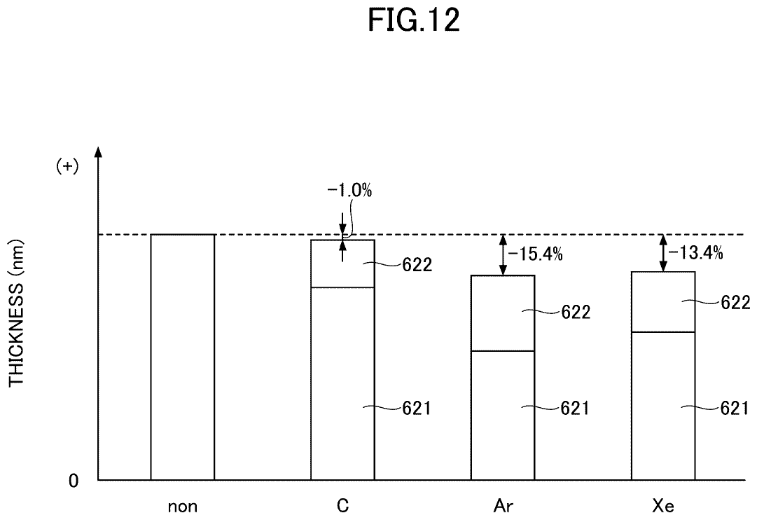

Next, the measurement results of ion implantation into SOC films will be described with reference to FIGS. 11A to 12. FIGS. 11A to 11D are graphs indicating examples of the results of Raman spectroscopy of SOC films. FIG. 11A indicates the result of an untreated (non) carbon-containing film 610, FIG. 11B indicates the result of C (carbon) ion implantation, FIG. 11C indicates the result of Ar (argon) ion implantation, and FIG. 11D indicates the result of Xe (xenon) ion implantation.

Here, as described above, control of the implantation amount at an implantation energy causes ions to be implanted substantially uniformly from the surface of the carbon-containing film to a predetermined depth, and inhibits ions from being implanted below the predetermined depth. Thus, as illustrated in FIG. 6B, the carbon-containing film 621 into which no ions are implanted and the carbon-containing film 622 into which ions are implanted can be formed.

In the case of C (carbon) ion implantation, the implantation energy may be, for example, 1 to 20 [keV], and the implantation amount may be, for example, in a range of 1×10¹⁴ to 5×10¹⁴ [atoms/cm²]. In the case of Ar (argon) ion implantation, the implantation energy may be, for example, 1 to 100 [keV], and the implantation amount may be, for example, in a range of 5×10¹⁴ to 5×10¹⁶ [atoms/cm²]. In the case of Xe (xenon) ion implantation, the implantation energy may be, for example, 1 to 200 [keV], and the implantation amount may be, for example, in a range of 1×10¹⁴ to 5×10¹⁵ [atoms/cm²].

As FIGS. 11A to 11D are illustrated by comparison, a peak was confirmed at a position indicated by outline arrow in FIGS. 11C and 11D. This peak indicates that DLC (diamond-like carbon) was formed. In other words, this indicates that implantation of Ar ions or Xe ions into the SOC film promoted change of the carbon-containing film from PLC (polymer-like carbon) to DLC (diamond-like carbon).

FIG. 12 is an example of a graph indicating the relationship between ion implantation and the film thickness of SOC films. In FIG. 12, the film thickness (THICKNESS (nm)) of an untreated (non) SOC film, a SOC film implanted with C (carbon) ions, a SOC film implanted with Ar (argon) ions, and a SOC film implanted with Xe (xenon) ions is indicated by bar graph length. The ratio (%) at which each SOC film implanted with ions was reduced with respect to the untreated (non) SOC film is also indicated.

As illustrated in FIG. 12, it was confirmed that the film thickness of the SOC films (carbon-containing films) implanted with ions was reduced. In other words, the reduction in the film thickness indicates an equivalent increase in the film density. From a SEM image (not illustrated) of a cross-section of the substrate W on which each SOC film was formed, it was confirmed that the SOC film implanted with ions changed into a two-layer structure including a lower carbon-containing film 621 and an upper carbon-containing film 622.

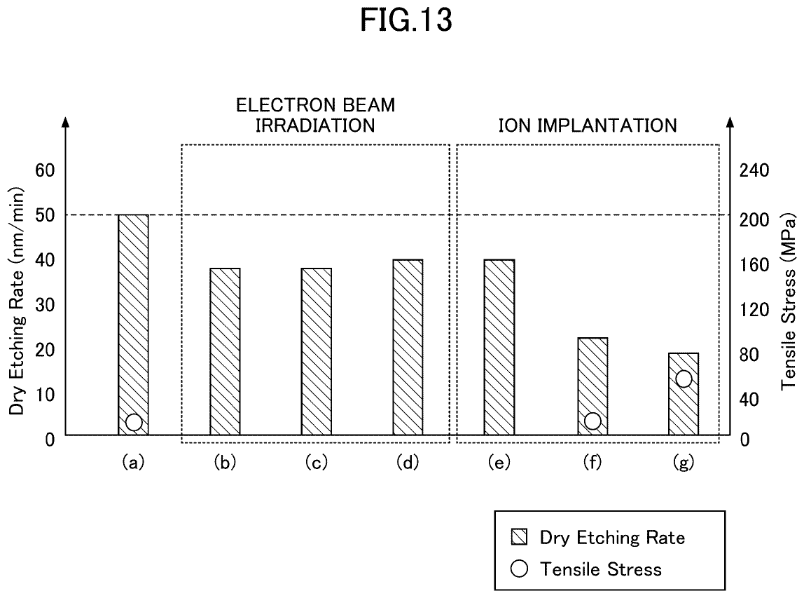

FIG. 13 is an example of a graph indicating the relationship between etching rate and film stress of KrF resist films. (a) indicates an untreated (non) KrF resist film, (b) indicates a KrF resist film irradiated with electron beams at an absorption dose of 10 kGy, (c) indicates a KrF resist film irradiated with electron beams at an absorption dose of 100 kGy, (d) indicates a KrF resist film irradiated with electron beams at an absorption dose of 1,000 kGy, (e) indicates a KrF resist film implanted with C (carbon) ions, (f) indicates a KrF resist film implanted with Ar (argon) ions, and (g) indicates a KrF resist film implanted with Xe (xenon) ions. The KrF resist films irradiated with electron beams illustrated in (b) to (d) correspond to the KrF resist films irradiated with electron beams illustrated in FIG. 7. The KrF resist films implanted with ions illustrated in (e) to (g) correspond to the KrF resist films implanted with ions illustrated in FIGS. 9A to 10.

The etching rate (Dry Etching Rate (nm/min)) of the KrF resist films under dry etching conditions is indicated by bar graph length. The film stress (tensile stress (MPa)) is indicated by outline circle.

As (a) and (b) to (d) are illustrated by comparison, it was confirmed that electron beam irradiation on the KrF resist films reduced the etching rate, i.e., improved the etching resistance. As (a) and (e) to (g) are illustrated by comparison, it was confirmed that ion implantation into the KrF resist films reduced the etching rate, i.e., improved the etching resistance. As the ions with which the films are irradiated, Ar and Xe are more preferable.

Although not illustrated, the film stress of the KrF resist films irradiated with electron beams illustrated in (b) to (d) is similar to that of the untreated (non) KrF resist film. Although not illustrated, the film stress of the KrF resist film implanted with carbon (C) ions illustrated in (e) is smaller than or similar to that of the KrF resist film implanted with Ar (argon) ions illustrated in (f). The film stress of the KrF resist film implanted with Ar (argon) ions illustrated in (f) is smaller than that of the KrF resist film implanted with Xe (xenon) ions illustrated in (g).

The difference between the film stress (first film stress) of the untreated (non) carbon-containing film (KrF resist film) illustrated in (a) and the film stress (second film stress) of the carbon-containing films (KrF resist films) subjected to the hardening treatment (reforming treatment) illustrated in (b) to (g) is preferably ±100 MPa or less (i.e., the difference between the first film stress and the second film stress is preferably −100 MPa or more and 100 MPa or less, and the absolute value of the difference between the first film stress and the second film stress is preferably 100 MPa or less). The film stress (second film stress) of the carbon-containing films (KrF resist films) subjected to the hardening treatment (reforming treatment) is preferably ±100 MPa or less. In other words, when a compressive stress is defined as positive and a tensile stress is defined as negative, the second film stress is preferably −100 MPa or more and 100 MPa or less. In this case, a carbon-containing film having a high etching resistance and a low stress can be formed.

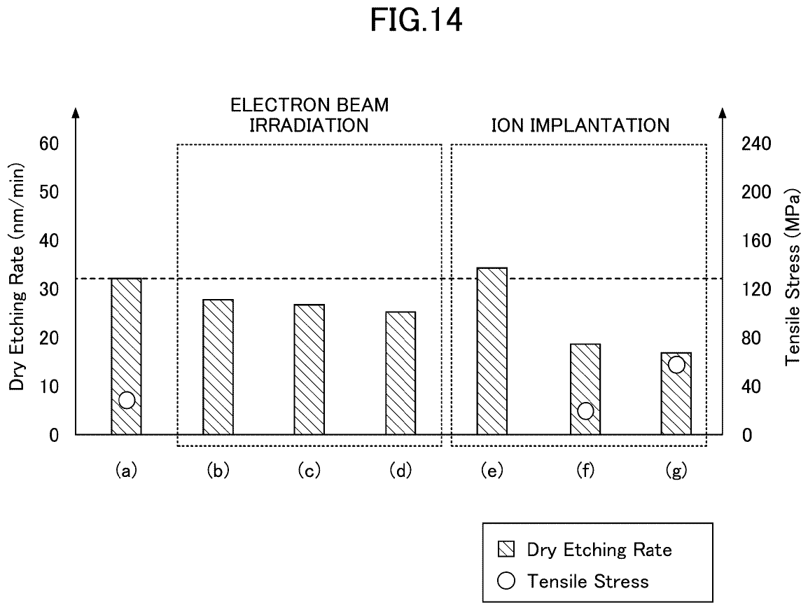

FIG. 14 is an example of a graph indicating the relationship between etching rate and film stress of SOC films. (a) indicates an untreated (non) SOC film, (b) indicates a SOC film irradiated with electron beams at an absorption dose of 10 kGy, (c) indicates a SOC film irradiated with electron beams at an absorption dose of 100 kGy, (d) indicates a SOC film irradiated with electron beams at an absorption dose of 1,000 kGy, (e) indicates a SOC film implanted with C (carbon) ions, (f) indicates a SOC film implanted with Ar (argon) ions, and (g) indicates a SOC film implanted with Xe (xenon) ions. The SOC films irradiated with electron beams illustrated in (b) to (d) correspond to the SOC films irradiated with electron beams illustrated in FIG. 8. The SOC films implanted with ions illustrated in (e) to (g) correspond to the SOC films implanted with ions illustrated in FIGS. 11A to 12.

The etching rate (Dry Etching Rate (nm/min)) of the SOC films under dry etching conditions is indicated by bar graph length. The film stress (Compressive Stress (MPa)) is indicated by outline circle.

As (a) and (b) to (d) are illustrated by comparison, it was confirmed that electron beam irradiation on the SOC films reduced the etching rate, i.e., improved the etching resistance. As (a) and (e) to (g) are illustrated by comparison, it was confirmed that ion implantation into the SOC films reduced the etching rate, i.e., improved the etching resistance. As the ions with which the films are irradiated, Ar and Xe are more preferable.

Although not illustrated, the film stress of the SOC films irradiated with electron beams illustrated in (b) to (d) is similar to that of the untreated (non) SOC film. Although not illustrated, the film stress of the SOC film implanted with carbon (C) ions illustrated in (e) is smaller than or similar to that of the SOC film implanted with Ar (argon) ions illustrated in (f). The film stress of the SOC film implanted with Ar (argon) ions illustrated in (f) is smaller than that of the SOC film implanted with Xe (xenon) ions illustrated in (g).

The difference between the film stress (first film stress) of the untreated (non) carbon-containing film (SOC film) illustrated in (a) and the film stress (second film stress) of the carbon-containing films (SOC films) subjected to the hardening treatment (reforming treatment) illustrated in (b) to (g) is preferably ±100 MPa or less (i.e., the difference between the first film stress and the second film stress is −100 MPa or more and 100 MPa or less, and the absolute value of the difference between the first film stress and the second film stress is 100 MPa or less). The film stress (second film stress) of the carbon-containing films (KrF resist films) subjected to the hardening treatment (reforming treatment) is preferably ±100 MPa or less. In other words, when a compressive stress is defined as positive and a tensile stress is defined as negative, the second film stress is preferably −100 MPa or more and 100 MPa or less. In this case, a carbon-containing film having a high etching resistance and a low stress can be formed.

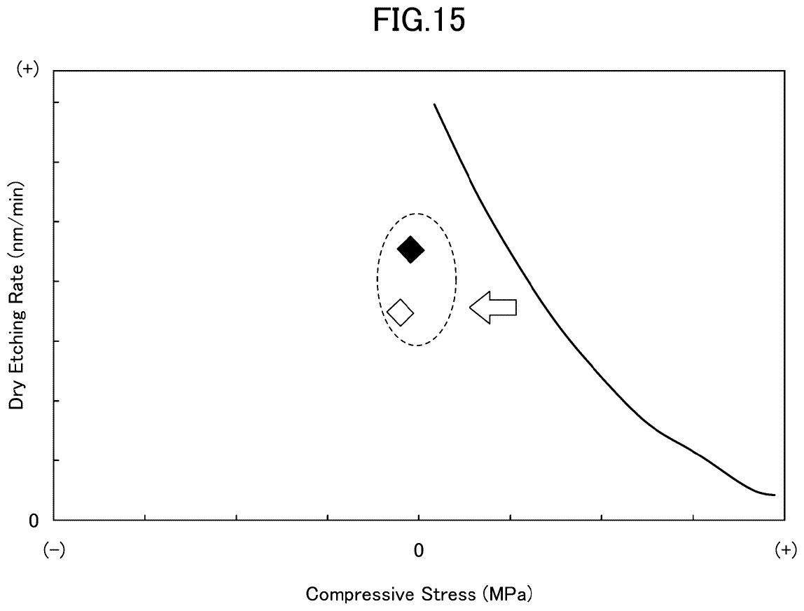

FIG. 15 is an example of a graph indicating the relationship between film stress and etching rate of a carbon-containing film. The solid line in FIG. 15 indicates the relationship between film stress and etching rate of various carbon-containing film materials. Carbon-containing films having a higher film density have a higher etching resistance. Here, as indicated by the solid line in FIG. 15, the higher the etching resistance (the lower the etching rate), the higher the film stress. That is, etching resistance and film stress are in a trade-off relationship, and it is difficult to achieve both of a high etching resistance and a low film stress by selecting carbon-containing film materials.

On the other hand, the carbon-containing film 620 formed by the method of forming a carbon-containing film of the present embodiment achieves both of a high etching resistance and a low film stress by having a two-layer structure including the carbon-containing film 621 having a low film stress and the carbon-containing film 622 having a high etching resistance as illustrated in FIG. 6B. Thus, the characteristic of the carbon-containing film 620 formed by the method of forming a carbon-containing film of the present embodiment can be brought to a region (a region indicated by a broken line) in which both of a low film stress and a high etching resistance are achieved, as indicated by rhombic markers in FIG. 15.

The configuration of the carbon-containing film formed on the substrate W is not limited to the configuration illustrated in FIG. 6B. FIGS. 16A and 16B are examples of schematic cross-sectional views illustrating other configuration states of carbon-containing films formed on the substrate W.

FIGS. 16A and 16B illustrate other embodiments of the present invention. In the configuration of the carbon-containing film illustrated in FIG. 16A, the step of forming a carbon-containing film 610 on the substrate W (first step, S101) and the step of forming a carbon-containing film 620 having a two-layer structure including a carbon-containing film 621 and a carbon-containing film 622 by subjecting the carbon-containing film 610 to the hardening treatment (reforming treatment) (second step, S102) are alternately repeated. A carbon-containing film may be formed by laminating a plurality of carbon-containing films 620 in this way. Thus, by the alternate arrangement of carbon-containing films 622 having a high etching resistance and carbon-containing films 621 having a low stress, a low film stress and a high etching resistance can both be achieved.

In the configuration illustrated in FIG. 16B, first, the step of forming a carbon-containing film (first carbon-containing film) 610 on the substrate W (first step, S101) and the step of forming a carbon-containing film 620 having a two-layer structure including a carbon-containing film 621 and a carbon-containing film 622 by subjecting the carbon-containing film (first carbon-containing film) 610 to the hardening treatment (reforming treatment) (second step, S102) are performed. Next, a step of forming a carbon-containing film (second carbon-containing film) having a film thickness smaller than that of the carbon-containing film (first carbon-containing film) 610 (third step) and a step of forming a carbon-containing film 630 by subjecting the entirety of the carbon-containing film (second carbon-containing film) having the smaller film thickness to the hardening treatment (reforming treatment) (fourth step) are performed. Further, the third step and the fourth step are alternately repeated. A carbon-containing film may be formed by laminating a plurality of carbon-containing films 630 on the carbon-containing film 620 in this way. Thus, the thickness of the carbon-containing films (carbon-containing film 622 and carbon-containing films 630) having a high etching resistance can be increased, to thereby enable further improvement of the etching resistance. In addition, positioning of the carbon-containing film 621 having a low stress between the substrate W and the carbon-containing films (carbon-containing film 622 and carbon-containing films 630) having a high etching resistance can inhibit increase in the film stress applied to the substrate W.

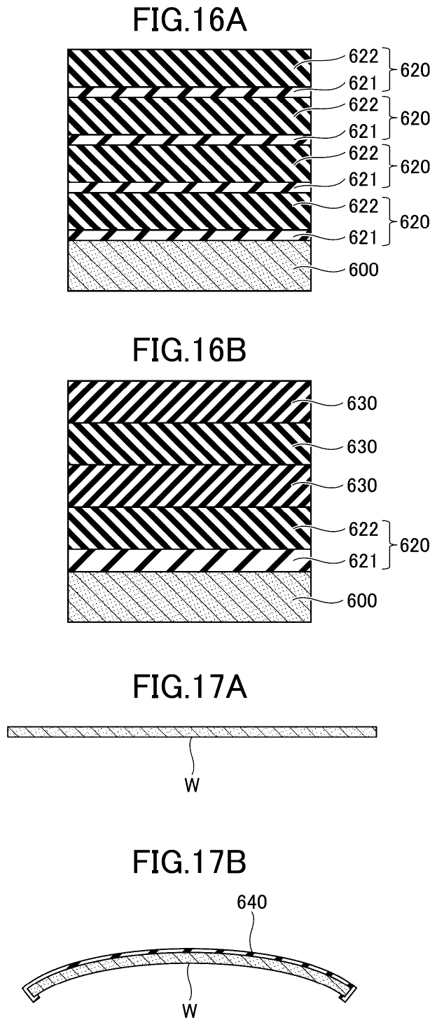

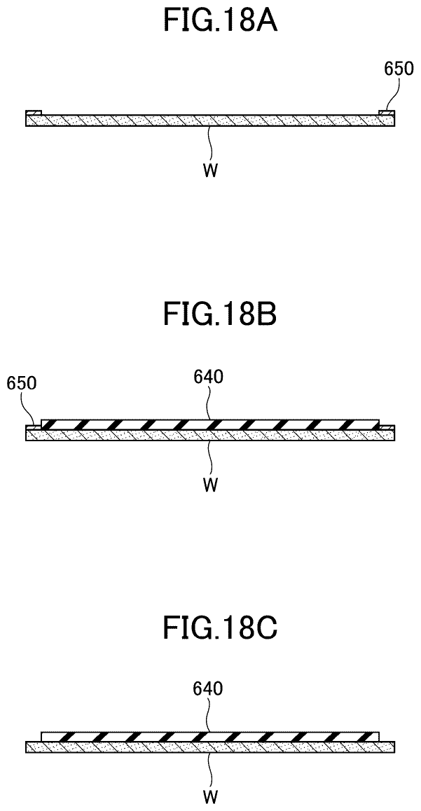

Next, warping of a substrate W caused by a carbon-containing film 640 will be described with reference to FIGS. 17A to 18C. FIGS. 17A and 17B are schematic cross-sectional views of a substrate W for illustrating warping of the substrate W when the carbon-containing film 640 is formed. FIG. 17A is an example of a view illustrating a state of the substrate W before the carbon-containing film 640 is formed. FIG. 17B is an example of a view illustrating a state of the substrate W after the carbon-containing film 640 is formed. By formation of the carbon-containing film 640 on the substrate W using the plasma processing apparatus 400 or the like, the carbon-containing film 640 is also formed on the edge of the substrate W, the bevel (outer circumferential surface of the substrate W), and the back surface of the substrate W. Here, when the carbon-containing film 640 is a film containing a compressive stress, the substrate W is deformed to be convex at the center thereof due to the film stress in the carbon-containing film 640.

FIGS. 18A to 18C are examples of schematic cross-sectional views of the substrate W for illustrating a process of forming the carbon-containing film 640 while inhibiting warpage of the substrate W.

As illustrated in FIG. 18A, a film formation inhibiting agent for inhibiting carbon-containing film formation is applied to the edge, the bevel, and the back surface of the substrate W, to form a film formation inhibiting layer 650. As the film formation inhibiting agent, an organic film or an organic coating film that can inhibit carbon-containing film growth, a pretreatment or the like such as hydrophilization, hydrophobization, and the like can be employed.

Next, as illustrated in FIG. 18B, the carbon-containing film 640 is formed on the substrate W. The formation of the carbon-containing film 640 may be film formation by a CVD method using the plasma processing apparatus 400. Thus, the carbon-containing film 640 is formed on a center region of the surface of the substrate W where the film formation inhibiting layer 650 is not formed. Meanwhile, formation of the carbon-containing film 640 on the edge, the bevel, and the back surface of the substrate W is inhibited by the film formation inhibiting layer 650.

Then, as illustrated in FIG. 18C, in a case where an organic film or an organic coating film that can inhibit carbon-containing film growth is formed as the film formation inhibiting layer, the film formation inhibiting layer 650 is removed. For the removal of the film formation inhibiting layer, for example, a plasma or back rinse can be employed.

In this way, by forming the carbon-containing film 640 on the center region of the surface of the substrate W excluding the edge, the bevel, and the back surface of the substrate W, it is possible to inhibit warpage of the substrate W. The method for inhibiting film formation on the edge, the bevel, and the back surface of the substrate W is not limited to this. For example, when forming a carbon-containing film, an annular member may be used to physically inhibit film formation on the bevel and the back surface of the substrate W.

The carbon-containing film 640 may be subjected to the hardening treatment (electron beam irradiation, ion implantation, and plasma irradiation). The timing to perform the hardening treatment may be before the film formation inhibiting layer 650 is removed or may be after the film formation inhibiting layer 650 is removed, and is not limited.

Although the embodiments and other particulars of the method of processing an organic film have been described above, the present disclosure is not limited to the embodiments and other particulars described above, and various modifications and improvements are applicable within the scope of the spirit of the present disclosure described in the claims.

What is claimed is:

1. A method of forming a carbon-containing film, the method comprising:
forming a first carbon-containing film on a substrate; and
reforming a surface layer of the first carbon-containing film,
wherein the first carbon-containing film formed in the forming of the first carbon-containing film has a first film stress,
the first carbon-containing film reformed in the reforming of the surface layer of the first carbon-containing film has a second film stress, and
a difference between the first film stress and the second film stress is ±100 MPa or less.

2. The method of forming a carbon-containing film according to claim 1,
wherein the first carbon-containing film reformed in the reforming of the surface layer of the first carbon-containing film includes:
a first region on a side toward the substrate; and
a second region on a side of the surface layer of the first carbon-containing film, the second region being reformed in the reforming of the surface layer of the first carbon-containing film.

3. The method of forming a carbon-containing film according to claim 2,
wherein a film density of the second region is greater than a film density of the first region.

4. The method of forming a carbon-containing film according to claim 3,
wherein a film stress of the first region is less than a film stress of the second region.

5. The method of forming a carbon-containing film according to claim 1,
wherein the reforming of the surface layer of the first carbon-containing film includes reforming the surface layer of the first carbon-containing film by ion implantation into the first carbon-containing film.

6. The method of forming a carbon-containing film according to claim 5,
wherein the ion implantation includes implanting an ion substantially uniformly from a surface of the first carbon-containing film to a predetermined depth by controlling an implantation amount at an implantation energy.

7. The method of forming a carbon-containing film according to claim 6,
wherein the ion implanted into the first carbon-containing film is any one of C, Ar, or Xe.

8. The method of forming a carbon-containing film according to claim 1,
wherein the reforming of the surface layer of the first carbon-containing film includes reforming the surface layer of the first carbon-containing film by electron beam irradiation on the first carbon-containing film.

9. The method of forming a carbon-containing film according to claim 1,
wherein the reforming of the surface layer of the first carbon-containing film includes reforming the surface layer of the first carbon-containing film by plasma irradiation on the first carbon-containing film.

10. The method of forming a carbon-containing film according to claim 1,
wherein the second film stress is 100 MPa or less.

11. The method of forming a carbon-containing film according to claim 1, further comprising:
repeating the forming of the first carbon-containing film and the reforming of the surface layer of the first carbon-containing film.

12. The method of forming a carbon-containing film according to claim 1, further comprising:
after the reforming of the surface layer of the first carbon-containing film, forming a second carbon-containing film having a film thickness less than that of the first carbon-containing film over the substrate; and
reforming an entirety of the second carbon-containing film.

13. The method of forming a carbon-containing film according to claim 12, further comprising:
repeating the forming of the second carbon-containing film and the reforming of the entirety of the second carbon-containing film.

14. The method of forming a carbon-containing film according to claim 1,
wherein the forming of the first carbon-containing film includes forming the first carbon-containing film on the substrate by spin coating.

15. The method of forming a carbon-containing film according to claim 1,
wherein the forming of the first carbon-containing film includes forming the first carbon-containing film on the substrate by CVD.

16. The method of forming a carbon-containing film according to claim 1,
wherein the forming of the first carbon-containing film includes forming the first carbon-containing film on the substrate, on whose edge, bevel, and back surface a film formation inhibiting layer is formed.

17. The method of forming a carbon-containing film according to claim 16, further comprising:
removing the film formation inhibiting layer.
